(19) United States
(12) Patent Application Publication
(10) Pub. No.: US 2025/0149373 A1
(43) Pub. Date: May 8, 2025

(54) SOFT TOUCH COATING MATERIALS FOR SUBSTRATE HANDLING

(71) Applicant: Applied Materials, Inc., Santa Clara, CA (US)

(72) Inventors: Nitin Deepak, Maharashtra (IN); Jennifer Sun, Fremont, CA (US); Mayur Govind Kulkarni, Karnataka (IN); Miguel S. Fung, Cupertino, CA (US); Darius "D" Alexander-Jones, Wildomar, CA (US); Chih Peng, Hayward, CA (US); Deenesh Padhi, Saratoga, CA (US); Kwangduk Douglas Lee, Redwood City, CA (US); Ganesh Balasubramanian, Fremont, CA (US); Juan Carlos Rocha-Alvarez, San Carlos, CA (US); Simmon Kuo, Tainan city (TW); Nagarajan Rajagopalan, San Jose, CA (US); Shankho Sen, Bangalore (IN)

(73) Assignee: Applied Materials, Inc., Santa Clara, CA (US)

(21) Appl. No.: 18/545,643

(22) Filed: Dec. 19, 2023

(30) Foreign Application Priority Data
Nov. 6, 2023 (IN) 202341075587

(51) Int. Cl. H01L 21/687

(52) U.S. Cl. CPC H01L 21/68757; H01L 21/68742

(57) ABSTRACT

Semiconductor components and systems having substrate contacting surfaces with a reduced hardness are provided. Systems and components include a ceramic, metallic, or non-metallic component for contacting a substrate. Systems and components include a layer of coating material on at least a portion of a substrate contacting surface of the component. Systems and components include where the component for contacting a substrate includes a component Vickers hardness value, and the layer of coating material exhibits a coating layer Vickers hardness value. Systems and components include where the coating layer Vickers hardness value is greater than or about 10% less than the component Vickers hardness value.

### TECHNICAL FIELD

The present technology relates to coating processes and semiconductor chamber components. More specifically, the present technology relates to modified components and component materials.

### BACKGROUND

Integrated circuits are made possible by processes which produce intricately patterned material layers on substrate surfaces. Producing patterned material on a substrate requires controlled methods of formation and removal of exposed material. Deposition and removal operations may include producing a remote plasma or a local plasma in a processing region of a semiconductor processing chamber, for example, between a showerhead or gas distributor and a substrate support. However, deposition and removal operations, as well as cleaning operations and the like, are often conducted in separate chambers. Thus, complex processes generally require transport between separate chambers utilizing one or more substrate handling components. However, existing substrate handling components may damage the wafer during handling due to the need to form such components from materials with a high degree of hardness, such that the component is capable of withstanding plasma conditions.

Thus, there is a need for improved systems and system components that can be used to produce high quality devices and structures. These and other needs are addressed by the present technology.

### SUMMARY

The present technology is generally directed to components for contacting a substrate. Components include a ceramic, metallic, or non-metallic component for contacting a substrate, a layer of coating material on at least a portion of a substrate contacting surface of the component. Components include where the component for contacting a substrate exhibits a component Vickers hardness value, and the layer of coating material comprises a coating layer Vickers hardness value, where the coating layer Vickers hardness value is greater than or about 10% less than the component Vickers hardness value.

In embodiments, the component for contacting a substrate comprises a lift pin, a transfer blade, a transfer arm, a vacuum chuck substrate support, an electrostatic chuck, an aligner, a load-lock contact, a substrate rotation module, or a combination thereof. In more embodiments, the component for contacting a substrate is a lift pin. Furthermore, in embodiments, the Vickers hardness of the layer of coating material is greater than or about 50% less than the Vickers hardness of the component. In yet more embodiments, the layer of coating material is an oxygen-containing material, a nitrogen-containing material, a fluorine-containing material, a metal-and-oxygen-containing material, a metal-and-fluorine-containing material, a metal-and-nitrogen-containing material, a metal-oxygen-and-fluorine-containing material, a metal-oxygen-and-nitrogen-containing material, or a metal-oxygen-fluorine-and-nitrogen-containing material, or a combination thereof. Additionally or alternatively, in embodiments, the layer of coating material includes aluminum, aluminum fluoride (AlF3), aluminum oxyfluoride (AlOxFy), aluminum nitride (AlN), calcium fluoride (CaF2), calcium oxyfluoride (CaOxFy), magnesium fluoride (MgF2), yttrium fluoride (YF3), yttrium oxyfluoride (YOxFy), zirconium fluoride (ZrF4), zirconium oxyfluoride (ZrOxFy), scandium fluoride (ScF3), or scandium oxyfluoride (ScOxFy), or a combination thereof. In embodiments, the Vickers hardness of the layer of coating material is less than or about 1200 HV. In more embodiments, the Vickers hardness of the layer of coating material is less than or about 650 HV. Embodiments include where the layer of coating material has a thickness from about 10 nm to about 10 micrometers. Further, in embodiments, the layer of coating material is applied utilizing chemical vapor deposition (CVD) and atomic layer deposition (ALD), physical vapor deposition (PVD), ion beam (IB) deposition, electron beam (EB) deposition, or electron beam ion-assisted deposition (EB-IAD), thermal spray, or combinations thereof.

The present technology is also generally directed to semiconductor processing systems.

Systems include a chamber body comprising sidewalls and a base, and a substrate support extending through the base of the chamber body. The substrate support includes a support plate having one or more lift pins, a shaft coupled with the support plate; and a layer of coating material on at least a portion of a substrate contacting surface of the support plate, the one or more lift pins, or a combination thereof. Systems include where support plate, the one or more lift pins, or a combination thereof include a component Vickers hardness value, and the layer of coating material comprises a coating layer Vickers hardness value, wherein the coating layer Vickers hardness value is greater than or about 10% less than the component Vickers hardness value.

In embodiments, the Vickers hardness of the layer of coating material is greater than or about 50% less than the Vickers hardness of the component. In more embodiments, the layer of coating material is an oxygen-containing material, a nitrogen-containing material, a fluorine-containing material, a metal-and-oxygen-containing material, a metal-and-fluorine-containing material, a metal-and-nitrogen-containing material, a metal-oxygen-and-fluorine-containing material, a metal-oxygen-and-nitrogen-containing material, or a metal-oxygen-fluorine-and-nitrogen-containing material, or a combination thereof. In embodiments, the Vickers hardness of the layer of coating material is less than or about 650 HV. In more embodiments, the layer of coating material has a thickness from about 10 nm to about 10 micrometers. Embodiments include where the layer is a multilayer stack, a nano-laminate stack, or a micro-laminate stack. In further embodiments, the layer of coating material uniformly coats the support plate, the one or more lift pins, or a combination thereof.

The present technology is also generally directed to substrate processing systems. Systems include a transfer region housing defining a transfer region, wherein a sidewall of the transfer region housing defines a sealable access for providing and receiving substrates, one or more substrate supports disposed within the transfer region comprising one or more lift pins, a transfer apparatus having one or more transfer arms, one or more transfer blades, or a combination thereof that engages a surface of the substrate, and a layer of coating material on at least a portion of a substrate contacting surface of a component comprising the one or more lift pins, the one or more substrate supports, one or more transfer arms, one or more transfer blades, or a combination thereof. Systems include where the component has a component Vickers hardness value, and the layer of coating material has a coating layer Vickers hardness value, where the coating layer Vickers hardness value is greater than or about 10% less than the component Vickers hardness value.

In embodiments, the component includes the one or more lift pins, the one or more transfer arms, the one or more transfer blades, or a combination thereof. In more embodiments, the Vickers hardness of the layer of coating material is greater than or about 50% less than the Vickers hardness of the component.

Such technology may provide numerous benefits over conventional techniques. For example, the methods may provide a coated substrate handling component exhibiting improved wafer handling properties. For example, coating discussed herein may be well suited for processing conditions, but exhibit improved softness. As such, substrates handled by or processed on the coated substrate handling component may exhibit less damage, such as reduced scratching, even on substrate backsides, thus also providing a reduced number of substrate defects and lower chamber contamination. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1A shows a schematic top plan view of an exemplary processing system according to some embodiments of the present technology.

FIG. 1B shows a schematic partial cross-sectional view of an exemplary chamber system according to some embodiments of the present technology.

FIG. 2 shows a schematic perspective view of a transfer region of an exemplary chamber system according to some embodiments of the present technology.

FIG. 3 shows a schematic view of an exemplary processing chamber according to some embodiments of the present technology.

FIG. 4 shows exemplary operations in a method according to some embodiments of the present technology.

FIG. 5 show schematic views of a component during operations in a deposition method according to some embodiments of the present technology.

FIG. 6 show schematic views of an exemplary processing chamber component formed the method according to some embodiments of the present technology.

Several of the figures are included as schematics. It is to be understood that the figures are for illustrative purposes and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Substrate processing can include time-intensive operations for adding, removing, or otherwise modifying materials on a wafer or semiconductor substrate. Efficient movement of the substrate may reduce queue times and improve substrate throughput. Such methods may include lift pins in the chamber body to facilitate retrieval and drop of off substrates by transfer robots. In such instance, the lift pins may raise the substrate off of the substrate support, such that the substrate may be transferred utilizing one or more transfer blades or arms.

However, as part of semiconductor processing technology, deposition and removal operations may include producing a process gas, and/or remote plasma or a local plasma in a processing region of a semiconductor processing chamber, for example, between a showerhead or gas distributor and a substrate support. Components of the semiconductor processing chamber may be or include a metal material, a metallic material, and/or a ceramic material, in order to reduced degradation and be inert in the processing chamber. Components of the semiconductor processing chamber, and particularly components that contact or support the substrate, such as lift pins, transfer arms or blades, vacuum chucks, electrostatic chucks, and the like, often damage the substrate due, as the durable, inert materials also exhibit a high degree of hardness. Moreover, substrate contact surfaces (also referred to as substrate handling components or surfaces) may include any substrate contact surface, including aligners, load-lock contacts, pins, substrate rotation modules, and the like. Regardless, existing substrate handling components can scratch or otherwise damage substrates.

The present technology overcomes these and other problems by coating one or more substrate handling components with carefully formed materials exhibiting a degree of hardness below the hardness of the substrate handling component. In addition, such materials may be carefully selected to both exhibit reduced hardness, while also being well suited for deposition and etch processes, including one or more plasma process. Surprisingly, coated substrate handling components according to the present technology may exhibit drastically reduced hardness values, such as Vickers hardness, of greater than or about 10% less than a Vickers hardness of existing substrate handling components. In such a manner, instances of substrate damage due to handling components may be significantly decreased.

After describing general aspects of a chamber according to embodiments of the present technology in which plasma processing may be performed, specific methodology and component configurations may be discussed. It is to be understood that the present technology is not intended to be limited to the specific films and processing discussed, as the techniques described may be used to improve a number of film formation processes, and may be applicable to a variety of processing chambers and operations.

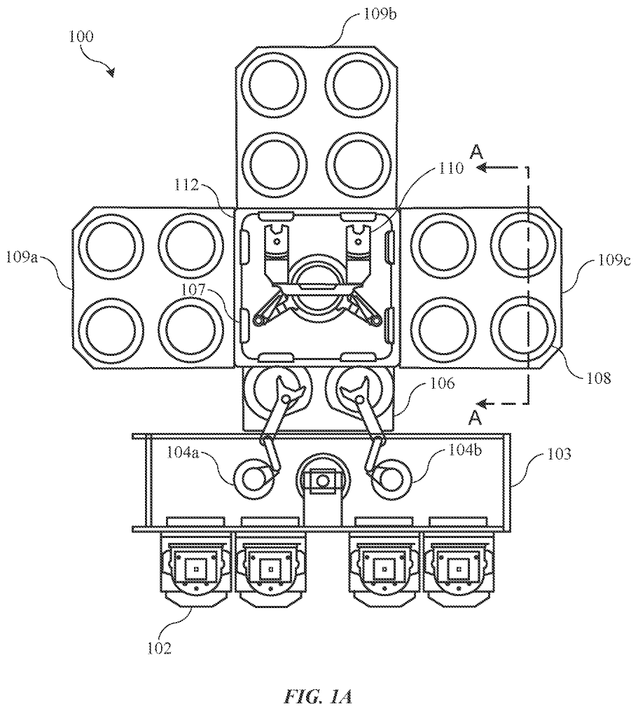

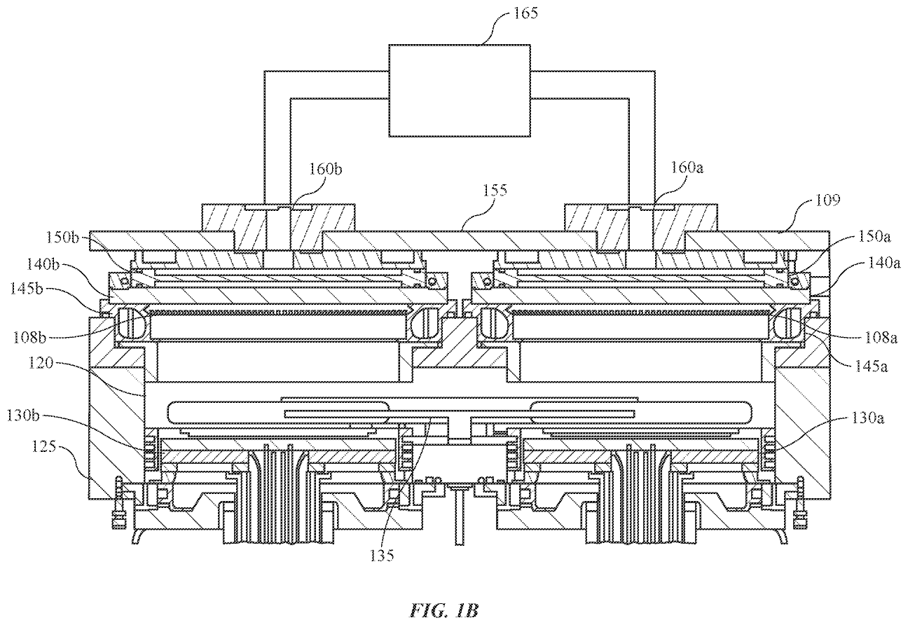

FIG. 1A shows a top plan view of one embodiment of a substrate processing tool or processing system 100 of deposition, etching, baking, and curing chambers according to some embodiments of the present technology. In the figure, a set of front-opening unified pods 102 supply substrates of a variety of sizes that are received within a factory interface 103 by robotic arms 104a and 104b and placed into a load lock or low pressure holding area 106 before being delivered to one of the substrate processing regions 108, positioned in chamber systems or quad sections 109a-c, which may each be a substrate processing system having a transfer region fluidly coupled with a plurality of processing regions 108. Although a quad system is illustrated, it is to be understood that platforms incorporating standalone chambers, twin chambers, and other multiple chamber systems are equally encompassed by the present technology. A second robotic arm 110 housed in a transfer chamber 112 may be used to transport the substrate wafers from the holding area 106 to the quad sections 109 and back, and second robotic arm 110 may be housed in a transfer chamber with which each of the quad sections or processing systems may be connected. Each substrate processing region 108 can be outfitted to perform a number of substrate processing operations including any number of deposition processes including cyclical layer deposition, atomic layer deposition, chemical vapor deposition, physical vapor deposition, as well as etch, pre-clean, anneal, plasma processing, degas, orientation, and other substrate processes.

Each quad section 109 may include a transfer region that may receive substrates from, and deliver substrates to, second robotic arm 110. The transfer region of the chamber system may be aligned with the transfer chamber having the second robotic arm 110. In some embodiments the transfer region may be laterally accessible to the robot. In subsequent operations, components of the transfer sections may vertically translate the substrates into the overlying processing regions 108. Similarly, the transfer regions may also be operable to rotate substrates between positions within each transfer region. The substrate processing regions 108 may include any number of system components for depositing, annealing, curing and/or etching a material film on the substrate or wafer. In one configuration, two sets of the processing regions, such as the processing regions in quad section 109a and 109b, may be used to deposit material on the substrate, and the third set of processing chambers, such as the processing chambers or regions in quad section 109c, may be used to cure, anneal, or treat the deposited films. In another configuration, all three sets of chambers, such as all twelve chambers illustrated, may be configured to both deposit and/or cure a film on the substrate.

As illustrated in the figure, second robotic arm 110 may include two arms for delivering and/or

retrieving multiple substrates simultaneously. For example, each quad section 109 may include two accesses 107 along a surface of a housing of the transfer region, which may be laterally aligned with the second robotic arm. The accesses may be defined along a surface adjacent the transfer chamber 112. In some embodiments, such as illustrated, the first access may be aligned with a first substrate support of the plurality of substrate supports of a quad section. Additionally, the second access may be aligned with a second substrate support of the plurality of substrate supports of the quad section. The first substrate support may be adjacent to the second substrate support, and the two substrate supports may define a first row of substrate supports in some embodiments. As shown in the illustrated configuration, a second row of substrate supports may be positioned behind the first row of substrate supports laterally outward from the transfer chamber 112. The two arms of the second robotic arm 110 may be spaced to allow the two arms to simultaneously enter a quad section or chamber system to deliver or retrieve one or two substrates to substrate supports within the transfer region.

Any one or more of the transfer regions described may be incorporated with additional chambers separated from the fabrication system shown in different embodiments. It will be appreciated that additional configurations of deposition, etching, annealing, and curing chambers for material films are contemplated by processing system 100. Additionally, any number of other processing systems may be utilized with the present technology, which may incorporate transfer systems for performing any of the specific operations, such as the substrate movement. In some embodiments, processing systems that may provide access to multiple processing chamber regions while maintaining a vacuum environment in various sections, such as the noted holding and transfer areas, may allow operations to be performed in multiple chambers while maintaining a particular vacuum environment between discrete processes. However, in embodiments, deposition and etch chambers utilizing substrate contact surfaces discussed herein may also be conducted at atmospheric conditions.

FIG. 1B shows a schematic cross-sectional elevation view of one embodiment of an exemplary processing tool, such as through a chamber system, according to some embodiments of the present technology. FIG. 1B may illustrate a cross-sectional view through any two adjacent processing regions 108 in any quad section 109, such as illustrated through line A-A in FIG. 1A. The elevation view may illustrate the configuration or fluid coupling of one or more processing regions 108 with a transfer region 120. For example, a continuous transfer region 120 may be defined by a transfer region housing 125. The housing may define an open interior volume in which a number of substrate supports 130 may be disposed. For example, as illustrated in FIG. 1A, exemplary processing systems may include four or more, including a plurality of substrate supports 130 distributed within the housing about the transfer region. The substrate supports may be pedestals as illustrated, although a number of other configurations may also be used. In some embodiments the pedestals may be vertically translatable between the transfer region 120 and the processing regions overlying the transfer region. The substrate supports may be vertically translatable along a central axis of the substrate support along a path between a first position and a second position within the chamber system. Accordingly, in some embodiments each substrate support 130 may be axially aligned with an overlying processing region 108 defined by one or more chamber components.

The open transfer region may afford the ability of a transfer apparatus 135, such as a carousel, to engage and move substrates, such as rotationally, between the various substrate supports. The transfer apparatus 135 may be rotatable about a central axis. This may allow substrates to be positioned for processing within any of the processing regions 108 within the processing system. The transfer apparatus 135 may include one or more end effectors that may engage substrates from above, below, and/or may engage exterior edges of the substrates for movement about the substrate supports. For instance, in embodiments, transfer apparatus discussed herein may transfer a substrate via edge-gripping. The transfer apparatus may receive substrates from a transfer chamber robot, such as robot 110 described previously. The transfer apparatus may then rotate substrates to alternate substrate supports to facilitate delivery of additional substrates.

Once positioned and awaiting processing, the transfer apparatus may position the end effectors or arms between substrate supports, which may allow the substrate supports to be raised past the transfer apparatus 135 and deliver the substrates into the processing regions 108, which may be vertically offset from the transfer region. For example, and as illustrated, substrate support 130a may deliver a substrate into processing region 108a, while substrate support 130b may deliver a substrate into processing region 108b. This may occur with the other two substrate supports and processing regions, as well as with additional substrate supports and processing regions in embodiments for which additional processing regions are included. In this configuration, the substrate supports may at least partially define a processing region 108 from below when operationally engaged for processing substrates, such as in the second position, and the processing regions may be axially aligned with an associated substrate support. The processing regions may be defined from above by a faceplate 140, as well as other lid stack components. In some embodiments, each processing region may have individual lid stack components, although in some embodiments components may accommodate multiple processing regions 108. Based on this configuration, in some embodiments each processing region 108 may be fluidly coupled with the transfer region, while being fluidly isolated from above from each other processing region within the chamber system or quad section.

In some embodiments the faceplate 140 may operate as an electrode of the system for producing a local plasma within the processing region 108. As illustrated, each processing region may utilize or incorporate a separate faceplate. For example, faceplate 140a may be included to define from above processing region 108a, and faceplate 140b may be included to define from above processing region 108b. In some embodiments the substrate support may operate as the companion electrode for generating a capacitively-coupled plasma between the faceplate and the substrate support. A pumping liner 145 may at least partially define the processing region 108 radially, or laterally depending on the volume geometry. Again, separate pumping liners may be utilized for each processing region. For example, pumping liner 145a may at least partially radially define processing region 108a, and pumping liner 145b may at least partially radially define processing region 108b. A blocker plate 150 may be positioned between a lid 155 and the faceplate 140 in embodiments, and again separate blocker plates may be included to facilitate fluid distribution within each processing region. For example, blocker plate 150a may be included for distribution towards processing region 108a, and blocker plate 150b may be included for distribution towards processing region 108b.

Lid 155 may be a separate component for each processing region, or may include one or more common aspects. In some embodiments, such as illustrated, lid 155 may be a single component defining multiple apertures 160 for fluid delivery to individual processing regions. For example, lid 155 may define a first aperture 160a for fluid delivery to processing region 108a, and lid 155 may define a second aperture 160b for fluid delivery to processing region 108b. Additional apertures may be defined for additional processing regions within each section when included. In some embodiments, each quad section 109-or multi-processing-region section that may accommodate more or less than four substrates, may include one or more remote plasma units 165 for delivering plasma effluents into the processing chamber. In some embodiments individual plasma units may be incorporated for each chamber processing region, although in some embodiments fewer remote plasma units may be used. For example, as illustrated a single remote plasma unit 165 may be used for multiple chambers, such as two, three, four, or more chambers up to all chambers for a particular quad section. Piping may extend from the remote plasma unit 165 to each aperture 160 for delivery of plasma effluents for processing or cleaning in embodiments of the present technology.

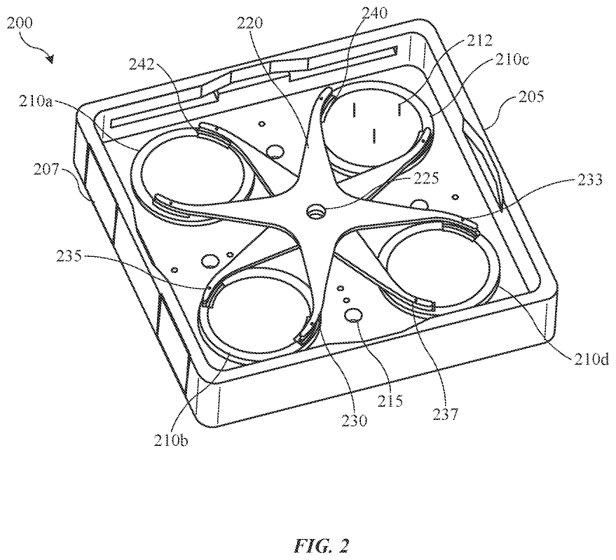

As noted, processing system 100, or more specifically quad sections or chamber systems incorporated with system 100 or other processing systems, may include transfer regions positioned below the processing chamber regions illustrated. FIG. 2 shows a schematic isometric view of an exemplary substrate processing system 200 according to some embodiments of the present technology. The system illustrated may include a transfer region housing 205 defining an internal volume or transfer region in which a number of components may be included. The transfer region may additionally be at least partially defined from above by processing chambers, such as processing chambers illustrated in quad sections 109 of FIG. 1A. A sidewall of the transfer region housing may define one or more access locations 207 through which substrates may be delivered and retrieved, such as by second robotic arm 110 as discussed above. Access locations 207 may be slit valves or other sealable access positions, which include doors or other sealing mechanisms to provide a hermetic environment within transfer region housing 205 in some embodiments. Although illustrated with two such access locations 207, it is to be understood that in some embodiments only a single access location 207 may be included. It is also to be understood that substrate processing system 200 may be sized to accommodate any substrate size, including 200 mm, 300 mm, 450 mm, or larger or smaller substrates, including substrates characterized by any number of geometries or shapes.

Within transfer region housing 205 may be a plurality of substrate supports 210 positioned about the transfer region volume. Although four substrate supports are illustrated, it is to be understood that any number of substrate supports are similarly encompassed by embodiments of the present technology. For example, greater than or about three, four, five, six, eight, or more substrate supports 210 may be accommodated in transfer regions according to embodiments of the present technology. Second robotic arm 110 may deliver a substrate to either or both of substrate supports 210a or 210b through the accesses 207, and may deliver substrates directly to a transfer apparatus within the transfer region in some embodiments. Similarly, second robotic arm 110 may retrieve substrates from these locations. Lift pins 212 may protrude from the substrate supports 210, and may allow the robot to access beneath the substrates. The lift pins may be fixed on the substrate supports, or at a location where the substrate supports may recess below, or the lift pins may additionally be raised or lowered through the substrate supports in some embodiments. Substrate supports 210 may be vertically translatable, and in some embodiments may extend up to processing chambers, such as processing chambers 108, positioned above the transfer region housing 205.

The transfer region housing 205 may provide access for alignment systems 215, which may include an aligner that can extend through an aperture of the transfer region as illustrated and may operate in conjunction with a laser, camera, or other monitoring device protruding or transmitting through an adjacent aperture, and that may determine whether a substrate being translated is properly aligned. Transfer region housing 205 may also include a transfer apparatus 220 that may be operated in a number of ways to position substrates and move substrates between the various substrate supports. In one example, transfer apparatus 220 may move substrates on substrate supports 210a and 210b to substrate supports 210c and 210d, which may allow additional substrates to be delivered into the transfer region.

Transfer apparatus 220 may include a central hub 225 that may include one or more shafts extending into the transfer region. Coupled with the central hub may be a first end effector 230, and a second end effector 235. First end effector 230 may include a plurality of first arms 233 extending radially or laterally outward from the central hub. Similarly, second end effector 235 may include a plurality of second arms 237 extending radially or laterally outward from the central hub. Although illustrated with a central body from which the arms extend, each of the end effectors may additionally include separate arms that are each coupled with the central hub 225. Any number of arms may be included in embodiments of the present technology. In some embodiments a number of first arms 233 may be similar or equal to the number of substrate supports 210 included in the chamber, and the number of second arms 237 may be similar or equal to the number of first arms 233. Hence, as illustrated, for four substrate supports, transfer apparatus 220 may include four arms for each of the first end effector and the second end effector. The arms may be characterized by any number of shapes and profiles, such as straight profiles, as well as arcuate profiles as illustrated. In addition, it should be clear that other shapes, such as transfer blades and the like may be utilized Although any profile may be utilized, in some embodiments an arcuate profile may accommodate a substrate, which may be circular in some embodiments. Furthermore, transfer apparatus 220 may include arms having shapes or profiles so as to contact more than one substrate surface.

The first end effector 230 may additionally include a plurality of first end pieces 240. Each first end piece 240 may be coupled with a separate first arm of the plurality of first arms 233. Similarly, second end effector 235 may additionally include a plurality of second end pieces 242. Each second end piece 242 may be coupled with a separate second arm of the plurality of second arms 237. Each end piece may also be characterized by an arcuate exterior profile to accommodate a circular or otherwise arcuate substrate. The end pieces may be used to contact substrates during transfer or movement. The end pieces as well as the end effectors may be made from or include a number of materials including conductive and/or insulative materials. The materials may be coated as discussed herein in order to reduce damage to substrates upon contact.

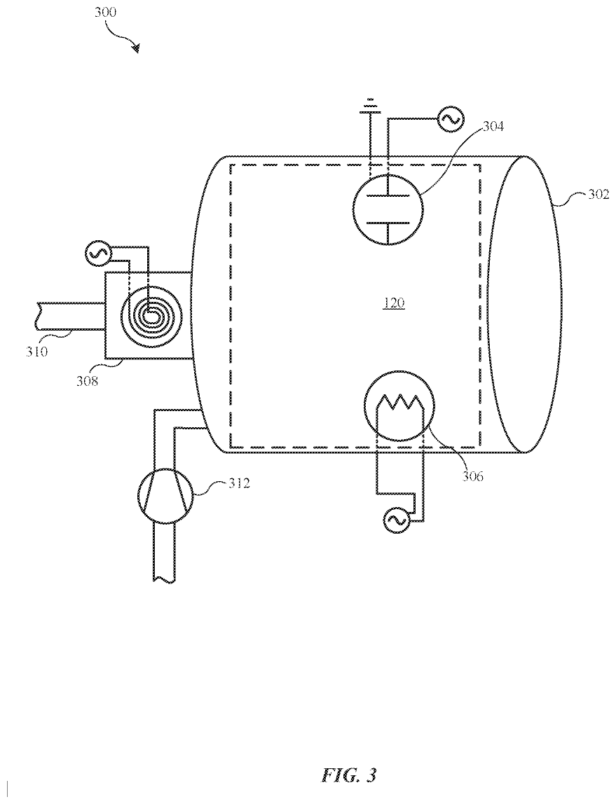

FIG. 3 shows a schematic view of an exemplary processing chamber 300 according to some embodiments of the present technology. The figure may illustrate an overview of a system incorporating one or more aspects of the present technology, and/or which may perform one or more operations according to embodiments of the present technology. Additional details of chamber 300 or methods performed may be described further below. Chamber 300 may be utilized to form coated components for semiconductor processing according to some embodiments of the present technology, although it is to be understood that the methods may similarly be performed in any chamber within which film formation may occur. Moreover, in embodiments, coating operations may be conducted in-situ in the processing chamber where one or more substrate contacting components are assembled. The processing chamber 300 may include a chamber body 302, a plasma system 304 inside the chamber body 302, a temperature control system 306, and a remote plasma system 308 coupled with the chamber body 302 and configured to provide plasma effluents to a processing region 320 of the chamber body 302.

A substrate handling component may be provided to the processing region 320 through a material feedthrough, such as a port or conduit, which may be sealed for processing using a slit valve, gate valve, or door. Precursors, as described below, may be provided to the chamber 300 through a gas supply system 310. While FIG. 3 illustrates a single inlet for the gas supply system 310, the chamber 300 may include multiple gas inlets coupled with the chamber body 302 at one or more locations. For example, a plasma precursor may be introduced to the chamber body through the remote plasma system 308, while a second gas inlet may provide gases for which plasma dissociation would negatively impact the deposition process. Gases may be removed from the chamber body 302 by a gas removal system 312. The gas removal system 312 may include a vacuum system, configured to facilitate reduced pressure operation during deposition processes and to evacuate the chamber to remove process effluents and unreacted process gases. Measurement and control systems may be coupled with the chamber to measure operating pressure in one or more places, such as in the gas supply system 310, the gas removal system 312, or in the processing region 320. In another example, the temperature control system 306 may include temperature sensors and a heating element configured to provide heat to the processing region 320 or to remove heat from the processing region 320. In this way, the chamber 300 may implement controlled deposition and removal processes, such as plasma etching and removal, and atomic layer deposition.

As part of implementing plasma processing of components for semiconductor processing in the chamber 300, in accordance with the methods described below, the plasma system 304 may be configured to form a plasma within the processing region 320. The plasma system 304 may be or include an indirect plasma system, such as an RF capacitively-coupled plasma, configured to form a plasma within the processing region 320 by generating sufficiently strong electric fields internal to the chamber body 302. In some embodiments, the plasma system 304 may be or include a direct plasma system, such that one or more electrode surfaces are disposed within the chamber body. In this way, the processing region 320 may be defined between a live electrode and a reference ground electrode of the plasma system 304. The plasma system 304 may also include control systems and power supply systems, such as impedance matching circuits and 13.56 MHz RF power supplies.

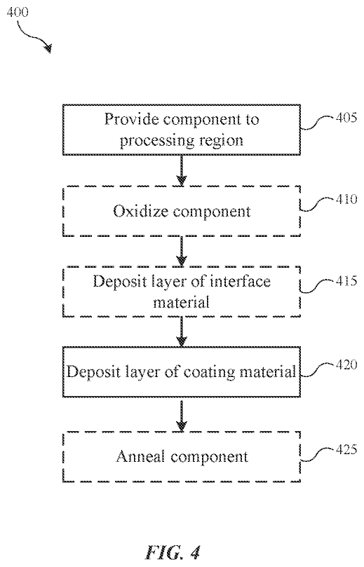

Similarly, the remote plasma system 308 may be or include a direct plasma system or an indirect plasma system, such as an inductively coupled RF plasma system or a capacitively coupled RF plasma system, which may be configured to decompose a precursor into plasma effluents that can be provided to the processing region 320. For example, the gas supply system 310 may include a quartz inlet tube coupled with a feedthrough to the chamber body 302. In such an arrangement, the remote plasma system 308 may be or include an ICP or a CCP system disposed external to the quartz inlet tube and configured to form a plasma within the quartz inlet tube. As further described in reference to FIG. 4, the precursor may include an inert carrier gas and a reaction precursor that may be or include a vapor or a gas. In this way, the remote plasma system 308 may form an indirect plasma in the precursor and may decompose the precursor. The decomposed precursor may be or include plasma effluents, which may be or include carrier gas, unreacted precursor, and plasma generated species. The plasma generated species may serve as reactants in a chemical reaction mediated deposition process, such as conformal deposition processes including, but not limited to, chemical vapor deposition (CVD) and atomic layer deposition (ALD), and direct line of sight deposition processes including, but not limited to, physical vapor deposition (PVD), ion beam (IB) deposition, electron beam (EB) deposition, or electron beam ion-assisted deposition (EB-IAD), thermal spray, and the like as well as combinations thereof. As with the plasma system 304, remote plasma system 308 may also include control systems and power supply systems, such as impedance matching circuits and 13.56 MHz RF power supplies.

The temperature control system 306 may be configured to maintain an internal temperature in the processing region in accordance with a processing method. For example, as part of atomic layer deposition, a deposition substrate, such as a substrate handling component, may be heated to a reaction temperature at which a particular reaction product is favored. In an illustrative example, a surface reaction that forms a layer of material on the deposition substrate may be thermodynamically favored at an elevated temperature. Moreover, in embodiments the present technology has found that by utilizing processing temperatures, such as deposition temperatures similar to temperatures experienced in a processing chamber, the coatings may exhibit an improved resistance to cracking and minimize the risk of delamination. As such, the temperature control system 306 may provide heat to the processing region. In some embodiments, the temperature control system may be at least partially integrated into the plasma system 304. For example, an electrode of the plasma system 304 may incorporate heating and/or cooling elements, permitting the plasma system to operate within a range of operating temperatures.

In some embodiments, the chamber 300 may be configured to prepare coated components for semiconductor processing for which the components are coated with one or more layers of material. As described in reference to methods and systems, below, the chamber 300 may permit the preparation of improved coated components for semiconductor processing, which may be incorporated into semiconductor processing systems. Such components may exhibit good thermal, mechanical, and/or chemical properties at processing conditions that are characteristic of plasma deposition and removal operations as part of semiconductor processing. Furthermore, surprisingly, components and systems prepared herein exhibited improved softness, and therefore greatly reduced risk of imparting damage to substrates.

FIG. 4 shows exemplary operations in a method 400 according to some embodiments of the present technology. The method may be performed in a variety of processing chambers, including processing chamber 300 described above. Method 400 may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated.

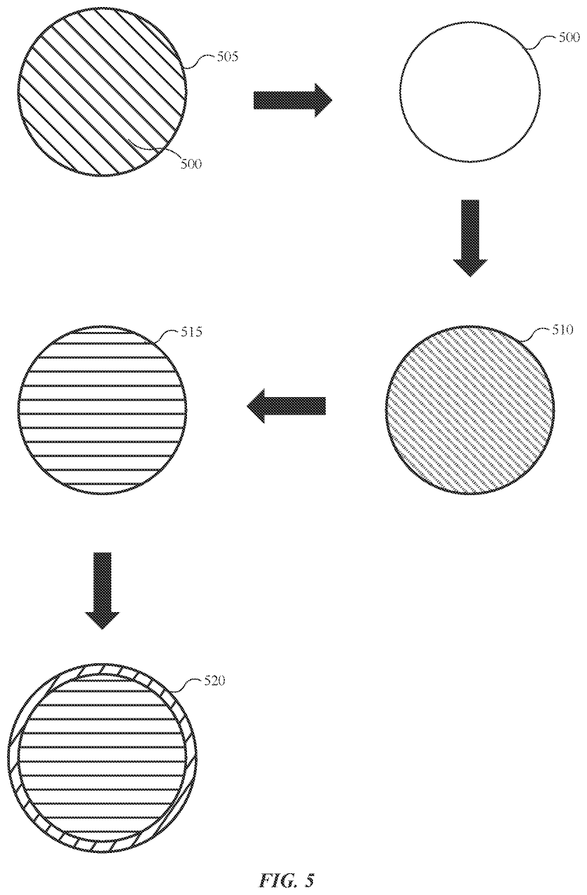

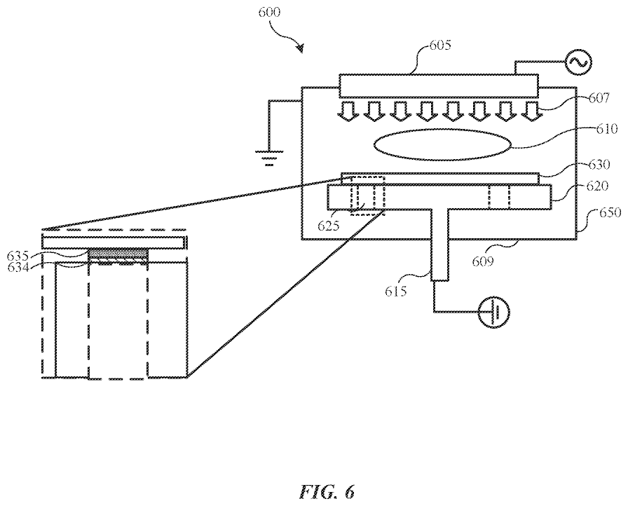

Method 400 describes operations shown schematically in FIG. 5, the illustrations of which will be described in conjunction with the operations of method 400. FIG. 6 illustrates an exemplary semiconductor processing system incorporating materials produced according to some embodiments of the method 400. It is to be understood that FIGS. 5-6 illustrate only partial schematic views, and a processing system may include subsystems as illustrated in the figures, as well as alternative subsystems, of any size or configuration that may still benefit from aspects of the present technology.

FIG. 5 shows schematic views of a substrate handling component 500 during operations of the method 400 according to some embodiments of the present technology. In some embodiments, the method 400 may include one or more operations preceding those illustrated in FIG. 5. For example, one or more processes may be implemented to form the substrate handling component 500 from a feedstock material. In embodiments, the substrate handling component 500 may be introduced into a processing chamber, such as the chamber 300, bearing a passivation layer 505. For example, the substrate handling component 500 may be or include aluminum nitride, aluminum oxide, aluminum carbide, as well as other materials, which, through exposure to oxygen during cleaning or through exposure to air at ambient conditions, may develop a passivation layer, such as an oxide passivation layer.

Method 400 may include additional operations prior to initiation of the listed operations. For example, as illustrated in FIG. 5, method 400 may include removing a passivation layer 505, such as a native oxide or surface oxide, prior to coating the component. Removing the passivation layer may include providing hydrogen to the processing region of the chamber. Hydrogen may permit a hydrogen plasma, a hydrogen-rich plasma, or a trace-hydrogen plasma to be formed in the processing region, as an approach to chemically reducing the passivation layer 505. The hydrogen may be provided to the processing region of the chamber with an inert carrier gas. In plasma systems, inert carrier gases, also referred to as “forming gases”, facilitate plasma ignition and control of plasma conditions. For example, providing the hydrogen with a given inert gas fraction may permit the plasma to operate under controlled plasma conditions, such as ionization fraction, ion temperature, or electron temperature.

Subsequent introducing hydrogen into the processing region, the method 400 may include striking a plasma in the processing region. The plasma may be or include a hydrogen plasma, and as such it may include energetic plasma species, such as hydrogen ions, hydrogen radicals, or metastable diatomic hydrogen. The hydrogen plasma may be formed in the processing region while the substrate handling component 500 is positioned in the processing region. The plasma treatment may be performed based on hydrogen supplied with a carrier gas, such as argon or helium, for generating the plasma, and the hydrogen may constitute a percentage material in the gas mixture.

During method 400, the substrate handling component 500 may be positioned in the processing region. At operation 405, method 400 may include delivering the substrate handling component 500 to the processing region of the processing chamber, such as processing chamber 300 described above, or other chambers that may include components as described above. The substrate handling component 500 may be any type of material and may be a metal-containing material, a metallic-containing material, or a ceramic-containing material in embodiments. For example, the substrate handling component 500 may include one or more metals and one or more of oxygen, fluorine, and nitrogen (e.g., a material comprising one or more metals and one or more of oxygen, fluorine, and nitrogen), and may be or include, but are not limited to, aluminum, magnesium, titanium, stainless steel, Hastelloy, yttria, aluminum oxide (Al₂O₃), aluminum oxyfluoride (AlOₓF_{y}), aluminum carbide (Al₄C₃), magnesium oxide (MgO), magnesium oxyfluoride (MgOₓF_{y}), titanium oxide (TiO₂), titanium oxyfluoride (TiOₓF_{y}), aluminum nitride (AlN), aluminum oxynitride (AlOₓN_{y}), silicon nitride (Si₃N₄), or silicon oxynitride (SiOₓN_{y}), or any combination thereof.

In some embodiments, method 400 may optionally include oxidizing the substrate handling component 500 at optional operation 410. Optional operation 410 may include introducing oxygen into the processing region of the chamber. Introducing oxygen into the processing region as part of plasma enhanced deposition may permit the formation of a controlled oxide layer on the substrate handling component 500. In contrast to the passivation layer 505, the controlled oxide layer may be formed under controlled conditions, such as in an oxygen plasma in the processing region, such that an oxide layer may be formed on the substrate handling component 500 with a characteristic and uniform thickness.

Additionally or alternatively, optional operation 410 may include thermal oxidation of the substrate handling component 500 subsequent removal of the passivation film 505. A surface oxide layer may impart improved control of thermal, mechanical, and/or chemical properties in a substrate handling component 500, for example, by acting as a diffusion barrier. In this way, it may be advantageous to reduce the substrate handling component 500 to remove the passivation layer 505, and subsequently to oxidize the substrate handling component 500 under controlled conditions to reform an oxide layer.

Subsequent oxidizing the substrate handling component 500 at optional operation 410, method 400 may include forming a layer of interface material 510 on the substrate handling component 500 at operation 410. Forming the layer of interface material 510 on the substrate handling component 500 may include undertaking operations of an PVD process, whereby the substrate handling component 500 may be coated on one or more exposed surfaces. However, as previously discussed, forming the layer of interface material 510 may be performed using a variety of deposition methods, including conformal deposition methods, such as ALD or CVD, where the component is uniformly coated. For example, operation 415 may include providing one or more interface deposition precursors or introducing plasma effluents of the one or more interface deposition precursors to the processing region. Plasma effluents may be or include plasma generated species that are formed by a remote plasma system, such as remote plasma system 308 of FIG. 3, in communication with the processing region. However, it is also contemplated that the plasma effluents may be formed locally to the substrate handling component 500. Introducing the plasma effluents may include introducing a carrier gas including the plasma effluents. In this way, introducing the plasma effluents into the processing region may expose the substrate handling component 500 to plasma effluents of one or more interface deposition precursors that have been subjected to plasma decomposition. Plasma effluents, therefore, may be or include ions, activated radicals, metastable species, and other decomposition products, and may be characterized by average energy distribution lower than that of a direct plasma system. Exposing the substrate handling component 500 to the plasma effluents may, in turn, result in the formation of an adsorbed monolayer of plasma effluents on the surface of the substrate handling component 500 that serves as a precursor to the formation of the layer of interface material 510. It is also contemplated that the substrate handling component 500 may be exposed to thermal and/or chemical effluents of the first precursor in addition to or alternative to plasma effluents.

In a second deposition operation, the plasma effluents, if formed, of the first precursor may be removed from the processing region by purging the processing region of gas, while retaining the substrate handling component 500 bearing the adsorbed monolayer. Purging the processing region may be implemented using a gas removal system, such as the gas removal system 312 of FIG. 3. Subsequent purging, a second precursor may be decomposed into second plasma effluents, such that the substrate handling component 500 is exposed to the second plasma effluents, if formed. However, it is also contemplated that the substrate handling component 500 may be exposed to thermal and/or chemical effluents of the second precursor in addition to or alternative to plasma effluents. The second precursor may be chosen such that it decomposes into plasma generates species that react with the monolayer adsorbed on the substrate handling component 500 to form the layer of interface material 510. Subsequent forming the layer of interface material 510, the unreacted plasma effluents and reaction byproducts may be removed by the gas removal system.

In embodiments, the one or more interface deposition precursors used may be dependent on the layer of interface material 510 to be formed. For example, one or more interface deposition precursors may include an oxygen-containing precursor, a nitrogen-containing precursor, a fluorine-containing precursors, a silicon-containing precursor, or a metal-containing precursor may be used.

The oxygen-containing precursor may be any oxygen-containing material used or useful in semiconductor processing. For example, the oxygen-containing precursor may be or include steam (H₂O), molecular oxygen (O₂), ozone (O₃), nitrous oxide (N₂O), hydrogen peroxide (H₂O₂), an oxygen-containing plasma, an alcohol-based compound, or an alcohol-based plasma.

The nitrogen-containing precursor may be any nitrogen-containing material used or useful in semiconductor processing. For example, the nitrogen-containing precursor may be or include nitrous oxide (N₂O), molecular nitrogen (N₂), ammonia (NH₃), hydrazine (N₂H₄), or nitrogen-based plasma.

The fluorine-containing precursor may be any fluorine-containing material used or useful in semiconductor processing. For example, the fluorine-containing precursor may be or include hydrogen fluoride (HF), ammonium fluoride (NH₄F), ammonium bifluoride ([NH₄]F·HF), a HF-pyridine complex, nitrogen trifluoride (NF₃), hexafluoroisopropanol (HFIP), tetrafluoropropanol (TFP), hexafluoroacetylacetonate (HHFAC), titanium tetrafluoride (TiF₄), tantalum pentafluoride (TaF₅), or tungsten hexafluoride (WF₆), or a fluorine-containing plasma.

The silicon-containing precursor may be any silicon-containing material used or useful in semiconductor processing. For example, the silicon-containing precursor may be or include silane (SiH₄), disilane (Si₂H₆), silicon tetrafluoride (SiF₄), silicon tetrachloride (SiCl₄), dichlorosilane (SiH₂Cl₂), or tetraethyl orthosilicate (TEOS).

The metal in the metal-containing precursor may be or include, for example, a rare earth element or a transition metal. For example, the metal-containing precursor may include aluminum, calcium, erbium, lanthanum, magnesium, scandium, titanium, yttrium, or zirconium. In embodiments, the metal-containing precursor may include a hexafluoroacetylacetone compound. For example, the metal may be in solution with hexafluoroacetylacetone (hfac). For example, the metal-containing precursor may be or include, but is not limited to, Mg(hfac)₂, or Mg(hfac)(dmg)H₂O, Al(hfac)₃, Y(hfac)₃.

In embodiments, the layer of interface material 510 may be a multilayer stack, a nano-laminate stack, or a micro-laminate stack of the one or more materials discussed above. Additionally, the layer of interface material 510 may be formed in a phase with increased stability. The increased stability may contribute to CTE modulation between the component and the coating material, increased adhesion, increased control of diffusion, nucleation, contamination, and/or porosity. In embodiments, the layer of interface material 510 may be in various crystallized phases, including spinel, garnet, an amorphous phase, and any other phase. However, in embodiments the coating may be in a crystalline or amorphous phase in order to diffuse into the component surface or interface material and exhibit diffusion bonding.

Depending on the precursors utilized during the deposition, the layer of interface material 510 may include, for example, an oxygen-containing material, a nitrogen-containing material, a fluorine-containing material, a metal-and-oxygen-containing material, a metal-and-fluorine-containing material, a metal-and-nitrogen-containing material, a metal-oxygen-and-fluorine-containing material, a metal-oxygen-and-nitrogen-containing material, or a metal-oxygen-fluorine-and-nitrogen-containing material, as previously discussed. In embodiments, the layer of interface material 510 may include multiple metals. For example, the layer of interface material 510 may be a magnesium-containing material, such as an aluminum-magnesium-and-oxygen-containing material (AlₓMg_{y}O), an yttrium-and-aluminum-containing material, such as yttrium aluminum garnet (YAG), or an erbium-and-aluminum-containing material, such as erbium aluminum garnet (EAG).

Subsequent depositing the optional layer of interface material 510 at operation 415, method 400 may include forming a layer of coating material 515 on the substrate handling component 500 at operation 420. Similar to forming the layer of interface material 510, forming the layer of coating material 515 on the substrate handling component 500 may include undertaking operations of one or more deposition process, whereby the substrate handling component 500 may have one or more surfaces coated with coating material 515. However, as previously discussed, forming the layer of coating material 315 may be performed using a variety of deposition methods. For example, operation 420 may include providing one or more coating deposition precursors or introducing plasma effluents of the one or more coating deposition precursors to the processing region. Plasma effluents may be or include plasma generated species that are formed by a remote plasma system, such as remote plasma system 308 of FIG. 3, in communication with the processing region. However, it is also contemplated that the plasma effluents may be formed locally to the substrate handling component 500. Introducing the plasma effluents may include introducing a carrier gas including the plasma effluents. In this way, introducing the plasma effluents into the processing region may expose the substrate handling component 500 to plasma effluents of one or more precursors that have been subjected to plasma decomposition. Plasma effluents, therefore, may be or include ions, activated radicals, metastable species, and other decomposition products, and may be characterized by average energy distribution lower than that of a direct plasma system. Exposing the substrate handling component 500 to the plasma effluents may, in turn, result in the formation of an adsorbed monolayer of plasma effluents on the surface of the substrate handling component 500 that serves as a precursor to the formation of the layer of coating material 515.

In a second deposition operation, the plasma effluents of the first precursor may be removed from the processing region by purging the processing region of gas, while retaining the substrate handling component 500 bearing the adsorbed monolayer. Purging the processing region may be implemented using a gas removal system, such as the gas removal system 312 of FIG. 3. Subsequent purging, a second precursor may be decomposed into second plasma effluents, such that the substrate handling component 500 is exposed to the second plasma effluents. The second precursor may be chosen such that it decomposes into plasma generates species that react with the monolayer adsorbed on the substrate handling component 500 to form the layer of coating material 515. Subsequent forming the layer of coating material 515, the unreacted plasma effluents and reaction byproducts may be removed by the gas removal system.

In some embodiments, the first and second precursors may be selected such that the layer of coating material 515 may be or include a lower hardness than the underlying substrate handling component 500. For example, the layer of coating material 515 may be an oxygen-containing material, a nitrogen-containing material, a fluorine-containing material, a metal-and-oxygen-containing material, a metal-and-fluorine-containing material, a metal-and-nitrogen-containing material, a metal-oxygen-and-fluorine-containing material, a metal-oxygen-and-nitrogen-containing material, or a metal-oxygen-fluorine-and-nitrogen-containing material. The oxygen-containing material may be or include, for example, a silicon-and-oxygen-containing material, having a tailored hardness value. The nitrogen-containing material may be or include, for example, a silicon-and-nitrogen-containing material. The fluorine-containing material may be or include, for example, a fluorine-doped silicon-containing material.

In embodiments, the one or more coating deposition precursors used may be dependent on the layer of coating material 515 to be formed. For example, one or more of an oxygen-containing precursor, a nitrogen-containing precursor, a fluorine-containing precursors, a silicon-containing precursor, or a metal-containing precursor may be used. The oxygen-containing precursor may be any oxygen-containing material used or useful in semiconductor processing. For example, the oxygen-containing precursor may be or include steam (H₂O), molecular oxygen (O₂), ozone (O₃), nitrous oxide (N₂O), hydrogen peroxide (H₂O₂), an oxygen-containing plasma, an alcohol-based plasma, or an alcohol-based plasma.

The nitrogen-containing precursor may be any nitrogen-containing material used or useful in semiconductor processing. For example, the nitrogen-containing precursor may be or include nitrous oxide (N₂O), molecular nitrogen (N₂), ammonia (NH₃), hydrazine (N₂H₄), or nitrogen-based plasma.

The fluorine-containing precursor may be any fluorine-containing material used or useful in semiconductor processing. For example, the fluorine-containing precursor may be or include hydrogen fluoride (HF), ammonium fluoride (NH₄F), ammonium bifluoride ([NH₄]F·HF), a HF-pyridine complex, nitrogen trifluoride (NF₃), hexafluoroisopropanol (HFIP), tetrafluoropropanol (TFP), hexafluoro-acetylacetonate (HHFAC), titanium tetrafluoride (TiF₄), tantalum pentafluoride (TaF₅), or tungsten hexafluoride (WF₆), or a fluorine-containing plasma.

The silicon-containing precursor may be any silicon-containing material used or useful in semiconductor processing. For example, the silicon-containing precursor may be or include silane (SiH⁴), disilane (Si₂H₆), silicon tetrafluoride (SiF₄), silicon tetrachloride (SiCl₄), dichlorosilane (SiH₂Cl₂), or tetraethyl orthosilicate (TEOS).

The metal in the metal-containing precursor may be or include, for example, a rare earth element or a transition metal. For example, the metal-containing precursor may include aluminum, calcium, erbium, lanthanum, magnesium, scandium, titanium, yttrium, or zirconium. In embodiments, the metal-containing precursor may include a hexafluoroacetylacetone compound. For example, the metal may be in solution with hexafluoroacetylacetone (hfac). For example, the metal-containing precursor may be or include, but is not limited to, Mg(hfac)₂, or Mg(hfac)(dmg)H₂O, Al(hfac)₃, Y(hfac)₃.

Regardless of the deposition method selected, as other deposition methods utilizing only one deposition operation may be possible, the first and second precursors are selected such that the coating has a lower degree of hardness than the underlying substrate handling component 500. Namely, as discussed above, by carefully selecting the coating material and deposition conditions, a coating is formed over the substrate handling component 500, improving the damage-free handling capabilities of the component without negatively impacting the strength and structure of the substrate handling component 500.

Thus, in embodiments, coatings formed according to the present technology may exhibit a hardness, such as a Vickers hardness, in embodiments, that is at least about 5% less than a hardness of the substrate handling component 500 underlying the coating, such as greater than or about 10%, such as greater than or about 15%, such as greater than or about 20%, such as greater than or about 25%, such as greater than or about 30%, such as greater than or about 35%, such as greater than or about 40%, such as greater than or about 45%, such as greater than or about 50%, such as greater than or about 55%, such as greater than or about 60%, such as greater than or about 65%, such as greater than or about 70%, such as greater than or about 75%, such as greater than or about 80%, such as greater than or about 85% less than a hardness of the underlying substrate handling component 500, or any ranges or values therebetween.

As an example, in embodiments, the layer(s) of coating material may have a Vickers hardness of less than or about 1300 HV, such as less than or about 1250 HV, such as less than or about 1200 HV, such as less than or about 1150 HV, such as less than or about 1100 HV, such as less than or about 1050 HV, such as less than or about 1000 HV, such as less than or about 950 HV, such as less than or about 900 HV, such as less than or about 850 HV, such as less than or about 800 HV, such as less than or about 750 HV, such as less than or about 700 HV, such as less than or about 650 HV, such as less than or about 600 HV, such as less than or about 550 HV, such as less than or about 500 HV, such as less than or about 450 HV, such as less than or about 400 HV, such as less than or about 300 HV, such as less than or about 250 HV, or any ranges or values therebetween. However, it should be clear that, when harder materials are utilized for substrate handling component 500, the hardness of the component may be according to any one or more of the above hardness values, or any value less than a hardness of substrate handling component 500.

Thus, in embodiments, a substrate handling component may have a substrate contacting surface having a hardness according to any one or more of the above values. Namely, in embodiments, the one or more layers of coating material 515 may form all or a portion of a substrate handling component, such as any portion configured to contact the substrate during transfer or processing. Moreover, in embodiments, the one or more layers of coating material may not include any materials having the same hardness, or a higher hardness, than substrate handling component, particularly on a portion of the substrate handling component configured to contact a substrate.

Moreover, the present technology has surprisingly found that by incorporating the coatings discussed herein at a tailored thickness, the coating may exhibit even further improvements in substrate handling without requiring a further reduction in coating hardness. Thus, in embodiments, the layer(s) of coating material 515 may each, or in total, be deposited at a thickness of greater than or about 1 nm, such as greater than or about 5 nm, such as greater than or about 10 nm, such as greater than or about 25 nm, such as greater than or about 50 nm, such as greater than or about 100 nm, such as greater than or about 250 nm, such as greater than or about 500 nm, such as greater than or about 750 nm, such as greater than or about 1 micrometer, such as greater than or about 1.5 micrometers, such as greater than or about 2 micrometers, such as greater than or about 2.5 micrometers, such as greater than or about 3 micrometers, such as greater than or about 3.5 micrometers, such as greater than or about 4 micrometers, such as greater than or about 4.5 micrometers, such as greater than or about 5 micrometers, such as greater than or about 5.5 micrometers, such as greater than or about 6 micrometers, such as greater than or about 6.5 micrometers, such as greater than or about 7 micrometers, such as greater than or about 7.5 micrometers, such as greater than or about 8 micrometers, such as greater than or about 8.5 micrometers, such as greater than or about 9 micrometers, such as greater than or about 9.5 micrometers, or such as up to about 10 micrometers, or any ranges or values therebetween. In embodiments, the thickness of each layer or all layers may be according to the above, or such as from about 500 nm to about 5 micrometers, such as from about 750 nm to about 3 micrometers, such as from about 1 micrometer to about 2.5 micrometers, or any ranges or values therebetween.

Nonetheless, in embodiments, the layer of coating material 515 may be an oxygen-containing material, a nitrogen-containing material, a fluorine-containing material, a metal-and-oxygen-containing material, a metal-and-fluorine-containing material, a metal-and-nitrogen-containing material, a metal-oxygen-and-fluorine-containing material, a metal-oxygen-and-nitrogen-containing material, or a metal-oxygen-fluorine-and-nitrogen-containing material, so long as the layer maintains the hardness values discussed above. In embodiments, the coating material may be generally defined by one or more of the chemical formulas: M₁M2OF, M₁M₂M₃OF, M₁M₂M₃ON, M₁M₂M₃ONF, where M₁, M₂, and/or M₃ are individually selected from a rare earth element or a transition metal. In embodiments, M₁, M₂, and/or M₃ are individually selected from aluminum, calcium, erbium, lanthanum, magnesium, scandium, titanium, yttrium, or zirconium.

Thus, in embodiments, the layer of coating material 515 may therefore include, for example, aluminum, aluminum nitride, aluminum fluoride (AlF₃), aluminum oxyfluoride (AlOₓF_{y}), calcium fluoride (CaF₂), calcium oxyfluoride (CaOₓF_{y}), magnesium fluoride (MgF₂), yttrium fluoride (YF₃), yttrium oxyfluoride (YOₓF_{y}), zirconium fluoride (ZrF₄), zirconium oxyfluoride (ZrOxFy), scandium fluoride (ScF₃), scandium oxyfluoride (ScOₓF_{y}), or combinations thereof, although any other layer of material previously discussed is contemplated, including a layer of coating material 515 including multiple metals. In one exemplary embodiment, the layer of coating material 515 may be a fluorine-containing material, an aluminum containing material, a yttrium containing material, or a combination thereof. Nonetheless, it should be clear that, regardless of the material utilized, the material is selected and formed so as to have improved softness as compared to the underlying substrate handling component.

In some embodiments, the constituent operations of the operation 420 may be repeated to deposit multiple monolayers, such that the layer of coating material 515 may be formed on a monolayer-by-monolayer basis, and the thickness of the layer of coating material 515 may be an integer multiple of the monolayer thickness and the number of repetitions of the operation 420. Additionally or alternatively, the layer of coating material 515 may be a multilayer stack, a nano-laminate stack, or a micro-laminate stack of the one or more materials discussed above. Additionally, the layer of coating material 515 may be formed in a phase with increased stability. The increased stability may contribute to CTE modulation between the component and the coating material, increased adhesion, increased control of diffusion, nucleation, contamination, and/or porosity. In embodiments, the layer of coating material may be in various crystallized phases, including spinel, garnet, an amorphous phase, and any other phase. However, in embodiments the coating may be in a crystalline or amorphous phase in order to diffuse into the component surface or interface material and exhibit diffusion bonding.

Furthermore, following operation 420, a second layer of coating material 520 may be formed overlying the layer of coating material 515, by repeating the operation with either the same set of first and second precursors or a different set of first and second precursors. For example, where the layer of coating material 515 may be or include aluminum fluoride, the second material 520 may be or include a different fluoride, such as yttrium aluminum fluoride, or another oxide, nitride, or fluoride, or may be a second layer of the same or similar coating material. As such, a coated substrate handling component 500 by the method 400 may include an optional controlled oxide layer, an optional layer of interface material 510, the layer of coating material 515, and one or more optional additional layers of different materials, such as the second layer of coating material 520.

Regardless of the number of layers, in embodiments, the substrate handling component 500 may be optionally annealed after the formation of one or more layers of coating material 515 at operation 425. The annealing operation may be conducted at temperatures sufficient to yield a crystalline or amorphous layer as discussed above, and may be conducted in an inert atmosphere, or in a reactive atmosphere.

A flowrate of the coating precursors or deposition precursors introduced to the chamber may depend at least in part on one or more parameters of the chamber, the substrate handling component 500, or the method 400. For example, the flowrate may be adjusted such that a plasma may form with a sufficient energy density or species density, such as ions, free electrons, or activated precursor, to facilitate, for example, reduction of the passivation layer 505 or deposition of the layer of coating material 515.

Related to the flowrate of the coating precursors or deposition precursors, a pulse size of the first precursor or of the second precursor may be less than or about 75 minutes. At times greater than 75 minutes, the substrate handling component 500 may be fully saturated and no longer accept the precursor to form a monolayer of material. Accordingly, the pulse size of the first precursor or of the second precursor may be less than or about 70 minutes, less than or about 65 minutes, less than or about 60 minutes, less than or about 55 minutes, less than or about 50 minutes, less than or about 45 minutes, less than or about 40 minutes, less than or about 35 minutes, less than or about 30 minutes, less than or about 25 minutes, less than or about 20 minutes, less than or about 15 minutes, less than or about 10 minutes, less than or about 5 minutes, less than or about 2 minutes, less than or about 1 minute, less than or about 50 seconds, less than or about 40 seconds, less than or about 30 seconds, less than or about 20 seconds, less than or about 10 seconds, or less.

Similarly a pulse size of the purge gas to purge the first precursor may be less than or about 120 minutes, such as less than or about 110 minutes, less than or about 100 minutes, less than or about 90 minutes, less than or about 80 minutes, less than or about 70 minutes, less than or about 65 minutes, less than or about 60 minutes, less than or about 55 minutes, less than or about 50 minutes, less than or about 45 minutes, less than or about 40 minutes, less than or about 35 minutes, less than or about 30 minutes, less than or about 25 minutes, less than or about 20 minutes, less than or about 15 minutes, less than or about 10 minutes, less than or about 5 minutes, less than or about 2 minutes, less than or about 1 minute, or less. The purge may be a longer duration than the precursor in order to ensure the precursors are fully removed from the processing region.

During method 400, such as during operations 410 and/or 415, a temperature within the processing chamber may be selected so as to provide robust coating characteristics to coating 515. Namely, as discussed above, it may be beneficial to deposit the coating at a temperature similar to a temperature experienced during substrate handling in order to reduced cracking and delamination.

Thus, in embodiments, deposition operations according to the present technology may operation at temperature of greater than or about 200° C., such as greater than or about 250° C, such as greater than or about 300° C., such as greater than or about 350° C., such as greater than or about 400° C., such as greater than or about 450° C., such as greater than or about 500° C., such as greater than or about 550° C, such as greater than or about 600° C., such as greater than or about 650° C., such as greater than or about 700° C., or such as less than or about 2,000° C., such as less than or about 1,750° C., such as less than or about 1,500° C., less than or about 1,25020 C., less than or about 1,000° C., less than or about 900° C., less than or about 800° C., less than or about 750° C., less than or about 725° C.., less than or about 700° C., less than or about 675° C., less than or about 650° C., less than or about 625° C., less than or about 600° C., less than or about 575° C., less than or about 550° C., less than or about 525° C., less than or about 500° C., less than or about 480° C., less than or about 460° C., less than or about 440° C., less than or about 420° C., less than or about 400° C., or any ranges or values therebetween.

Additionally, during method 400, such as during operations 410 and/or 415, a pressure within the processing chamber may be maintained at less than or about 50 mTorr. Again, while higher pressures may be employed, depositions of the present technology may be operated at pressures less than or about 50 mTorr, such as less than or about 45 mTorr, less than or about 40 mTorr, less than or about 35 mTorr, less than or about 30 mTorr, less than or about 25 mTorr, less than or about 20 mTorr, less than or about 15 mTorr, less than or about 10 mTorr, less than or about 7 mTorr, less than or about 5 mTorr, less than or about 3 mTorr, less than or about 1 mTorr, or any ranges or values therebetween, in addition to atmospheric pressure.

In addition to improved softness, and thus reduced damage to components, the method 400 and its constituent operations may provide one or more improvements to plasma enhanced deposition processes for depositing materials layers onto a substrate processing. For example, the method 400 may provide a coated component for substrate handling characterized by a core shell structure, where the core may be or include a ceramic material of the component, such as aluminum nitride, aluminum oxide, aluminum carbinde, or any other ceramic material, with one or more shells, such as a transition metal fluoride or a rare earth fluoride. In embodiments, the inclusion of an interface between the core and shell may provide one or more desirable properties. For example, the interface may provide CTE modulation between the core and the shell, increase adhesion between the core and the shell, serve as a diffusion barrier, control nucleation, control or remove contamination, or control porosity. Even further, plasma removal of a native passivation layer 505 may improve control of surface chemistry and therefore improves the thermal, mechanical, and/or chemical properties of coated components for semiconductor processing. However, in embodiments, it should be understood that the interface or passivation layer removal may not be necessary to form the soft coating layer discussed herein.

As will be described further with regard to FIG. 6, the substrate handling component may be, but is not limited to a lift pin, a transfer arm, a transfer blade, a vacuum chuck, an electrostatic chuck, a substrate aligner, a load-lock contact, a substrate rotation apparatus (such as a substrate rotation module), as well as other components that contact the substrate during processing. These enumerated components regularly contact substrates during processing, and can therefore exhibit reduced scratching and damage to substrates by utilizing the coating discussed herein. Moreover, due at least in part to the reduced risk of damage, substrate defects as well as chamber contamination (e.g. particles scratched from a substrate) may also be decreased.

FIG. 6 show schematic views of an exemplary plasms processing system including one or more components formed by the method according to some embodiments of the present technology. FIG. 6 further illustrates details relating to a semiconductor processing system 600, and one or more components that may be incorporated into system 600 that may be or include a coated component for substrate handling. The coated component for substrate handling, in turn, may be formed by coating a component for substrate handling, such as the coated component for substrate handling prepared by the method 400 discussed above. System 600 is understood to include any feature or aspect of a semiconductor processing chamber, and may be used to perform semiconductor processing operations including deposition, removal, and cleaning operations. System 600 may show a partial view of the chamber components being discussed and that may be incorporated in a typical semiconductor processing system, and may illustrate a view across a center of the pedestal and gas distributor, which may otherwise be of any size. Any aspect of system 600 may also be incorporated with other processing chambers or systems as will be readily understood by the skilled artisan.

System 600 may include a semiconductor processing chamber 650 including a showerhead 605, through which precursors 607 may be delivered for processing, and which may be configured to form a plasma 610 in a processing region between the showerhead 605 and a pedestal or substrate support 615. The showerhead 605 is shown at least partially internal to the chamber 650, and may be understood to be electrically isolated from the chamber 650. In this way, the showerhead 605 may act as a live electrode or as a reference ground electrode of a direct plasma system to expose a substrate held on the substrate support 615 to plasma generated species. The substrate support 615 may extend through the base of the chamber 650. The substrate support 615 may include a support platen 620, which may hold a semiconductor substrate 630 during deposition or removal processes used to form patterned structures on the semiconductor substrate 630. As illustrated, the support platen 620 may include one or more lift pins 625 for vertically translating the substrate 630 after processing, to aid in removing substrate 630 from the system 600. The lift pin 625 may be or include a coated component for substrate handling prepared in accordance with embodiments of method 400.

The support platen 620 may incorporate embedded electrodes to provide the electrostatic field employed to hold the semiconductor substrate, and may also include a thermal control system that may facilitate processing operations including, but not limited to, deposition, etching, annealing, or desorption. In some embodiments, the support platen 620 may incorporate a plate, a perforated plate, a mesh, a wire screen, or any other distributed arrangement of conductive elements. The embedded electrodes may be or include a tuning electrode to provide further control over the plasma 610, for example, by adjusting an electric field near the surface of the support platen. Similarly, a bias electrode and/or an electrostatic chucking electrode, may be coupled with the support platen 620. The bias electrode may be coupled with a source of electric power, such as a DC power, pulsed DC power, RF bias power, a pulsed RF source or bias power, or a combination of these or other power sources. In this way, the substrate support 615 and the support platen 620 may be used during plasma processing operations not only to hold the semiconductor substrate 630, but also to tune the conditions of the plasma 610. Tuning the conditions of the plasma may include implementing automatic impedance matching to maintain plasma conditions during plasma processing operations, for example, while the composition of the plasma 610 is varied or as the surface of the semiconductor substrate 630 changes, for example, due to deposition of dielectric films onto electrode surfaces. In this way, precise control of the plasma 610 may depend on the material properties of the substrate support 615 and the support platen 620.

In some cases, the lift pin 625 or other chamber components, such as support platen 620, may be formed by coating a substrate handling component with a layer of interface material 634 and a layer of coating material 635. For example, a substrate handling component may be treated to form a layer of interface material 634 and then treated to deposit a layer of coating material 635, such as a corrosion-resistant and/or erosion-resistant material, on the layer of interface material 634. Prior and/or subsequent operations, such as annealing, machining, incorporating electrical components, may be applied to finish the component, providing a working component that can be incorporated in a plasma system. An advantage of using a coated substrate handling component, for example, may include that a finished component with one or more layers of coating material 635 may serve as a refractory conductor, with favorable thermal deformation characteristics and chemical resistance to plasma etching, as well as electrical conductivity. Additionally, the layer of interface material 634 may serve to increase the benefits of the layer of coating material 635.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology. Additionally, methods or processes may be described as sequential or in steps, but it is to be understood that the operations may be performed concurrently, or in different orders than listed.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include

plural references unless the context clearly dictates otherwise. Thus, for example, reference to “a precursor” includes a plurality of such precursors, and reference to “the layer” includes reference to one or more layers and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A component for contacting a substrate comprising:
a ceramic, metallic, or non-metallic component for contacting a substrate;
a layer of coating material on at least a portion of a substrate contacting surface of the component;
wherein the component for contacting a substrate comprises a component Vickers hardness value, and the layer of coating material comprises a coating layer Vickers hardness value, wherein the coating layer Vickers hardness value is greater than or about 10% less than the component Vickers hardness value.

2. The component of claim 1, wherein the component for contacting a substrate comprises a lift pin, a transfer blade, a transfer arm, a vacuum chuck substrate support, an electrostatic chuck, an aligner, a load-lock contact, a substrate rotation module, or a combination thereof.

3. The component of claim 2, wherein the component for contacting a substrate comprises a lift pin.

4. The component of claim 3, wherein the Vickers hardness of the layer of coating material is greater than or about 50% less than the Vickers hardness of the component.

5. The component of claim 1, wherein the layer of coating material is an oxygen-containing material, a nitrogen-containing material, a fluorine-containing material, a metal-and-oxygen-containing material, a metal-and-fluorine-containing material, a metal-and-nitrogen-containing material, a metal-oxygen-and-fluorine-containing material, a metal-oxygen-and-nitrogen-containing material, or a metal-oxygen-fluorine-and-nitrogen-containing material, or a combination thereof.

6. The component of claim 5, wherein the layer of coating material comprises aluminum, yttria, aluminum fluoride (AlF₃), aluminum oxyfluoride (AlOₓF_{y}), aluminum nitride (AlN), calcium fluoride (CaF₂), calcium oxyfluoride (CaOₓF_{y}), magnesium fluoride (MgF₂), yttrium fluoride (YF₃), yttrium oxyfluoride (YOₓF_{y}), zirconium fluoride (ZrF₄), zirconium oxyfluoride (ZrOₓF_{y}), scandium fluoride (ScF₃), or scandium oxyfluoride (ScOₓF_{y}), or a combination thereof.

7. The component of claim 1, wherein Vickers hardness of the layer of coating material is less than or about 1200 HV.

8. The component of claim 7, wherein Vickers hardness of the layer of coating material is less than or about 650 HV.

9. The component of claim 1, wherein the layer of coating material has a thickness from about 10 nm to about 10 micrometers.

10. The component of claim 1, wherein the layer of coating material is applied utilizing chemical vapor deposition (CVD) and atomic layer deposition (ALD), physical vapor deposition (PVD), ion beam (IB) deposition, electron beam (EB) deposition, or electron beam ion-assisted

11. A semiconductor processing system, comprising:
a chamber body comprising sidewalls and a base;
a substrate support extending through the base of the chamber body, wherein the substrate support comprises:
a support plate comprising one or more lift pins; and
a shaft coupled with the support plate;
a layer of coating material on at least a portion of a substrate contacting surface of the support plate, the one or more lift pins, or a combination thereof, wherein the support plate, the one or more lift pins, or a combination thereof comprises a component Vickers hardness value, and the layer of coating material comprises a coating layer Vickers hardness value, wherein the coating layer Vickers

12. The system of claim 11, wherein the Vickers hardness of the layer of coating

13. The system of claim 11, wherein the layer of coating material is an oxygen-containing material, a nitrogen-containing material, a fluorine-containing material, a metal-and-oxygen-containing material, a metal-and-fluorine-containing material, a metal-and-nitrogen-containing material, a metal-oxygen-and-fluorine-containing material, a metal-oxygen-and-nitrogen-containing material, or a

14. The system of claim 11, wherein Vickers hardness of the layer of coating material is less than or about 650 HV.

15. The system of claim 11, wherein the layer of coating material has a thickness from about 10 nm to about 10 micrometers.

16. The system of claim 11, wherein the layer comprises a multilayer stack, a nano-laminate stack, or a micro-laminate stack.

17. The system of claim 11, wherein the layer of coating material uniformly coats the support plate, the one or more lift pins, or a combination thereof.

18. A substrate processing system comprising:
a transfer region housing defining a transfer region, wherein a sidewall of the transfer region housing defines a sealable access for providing and receiving substrates;
one or more substrate supports disposed within the transfer region comprising one or more lift pins;
a transfer apparatus comprising one or more transfer arms, one or more transfer blades, or a combination thereof that engages a surface of the substrate; and
a layer of coating material on at least a portion of a substrate contacting surface of a component comprising the one or more lift pins, the one or more substrate supports, one or more transfer arms, one or more transfer blades, or a combination thereof, wherein the component comprises a component Vickers hardness value, and the layer of coating material comprises a coating layer Vickers hardness value, wherein the coating layer Vickers hardness value is greater than or about 10% less than the component Vickers hardness value.

19. The processing system of claim 18, wherein the component comprises the one or more lift pins, the one or more transfer arms, the one or more transfer blades, or a combination thereof.

20. The processing system of claim 18, wherein the Vickers hardness of the layer of coating material is greater than or about 50% less than the Vickers hardness of the component.
